(19) United States
(12) Patent Application Publication
(10) Pub. No.: US 2018/0188785 A1
(43) Pub. Date: Jul. 5, 2018

(54) ASYNCHRONOUS TEMPERATURE CONTROL INTEGRATED DEVICE

(71) Applicant: EVGA CORPORATION, New Taipei City (TW)

(72) Inventor: Tai-Sheng Han, New Taipei City (TW)

(21) Appl. No.: 15/436,736

(22) Filed: Feb. 17, 2017

(30) Foreign Application Priority Data
Dec. 30, 2016 (TW) 105220092

(51) Int. Cl. G06F 1/20; H05K 7/20; G06F 1/04

(52) U.S. Cl. CPC G06F 1/206; G06F 1/04; H05K 7/20909

(57) ABSTRACT

An asynchronous temperature control integrated device includes a graphics card body including a graphics processor and a power supply circuit, a first heat dissipation device, at least one first temperature sensor arranged at one side of the first heat dissipation device, at least one second heat dissipation device arranged on the power supply circuit, at least one second temperature sensor arranged at one side of the second heat dissipation device, and a control device arranged on the graphics card body. As such, two groups of heat dissipation device and temperature sensor are provided to respectively detect the temperatures of two major heat sources on the graphics card body, and the control device is operable to individually control the heat dissipation performances of the two heat dissipation devices to make time and efficient use of the operations of the heat dissipation devices.

### (a) TECHNICAL FIELD OF THE INVENTION

The present invention relates generally to an asynchronous temperature control integrated device, and more particularly to an asynchronous temperature control integrated device that conducts an instantaneous and effective driving operation, in a manner of being free of extra power consumption, on individual heat sources located on a graphics card to individually control heat dissipation devices associated with the heat sources.

### (b) DESCRIPTION OF THE PRIOR ART

The advent of the high image quality era causes display screens, such as televisions, computers, game consoles, and movies evolving step by step from DVD, blue ray, to 4K, among which a major difference is “definition” or “resolution”. For computers, a high resolution image means computations on an increased number of pixel. Thus, in addition to the performance of the central processing unit, the performance of a graphics card also imposes a direct influence on the quality of a displayed image. And, accordingly, the amount of heat generated during the operation of hardware must be greatly increased. Effective and timely removal of thermal energy generated by a large number of heat sources (including a central processing, a graphics card, and a power supply device) is now one of the major factors that affect long-term operation of modern computers.

Considering a heat dissipation fan, a high-speed operation indicates a high efficiency of heat dissipation and would also amount to increasing accumulation of power consumption. If heat is not properly and timely removed, then the hardware might get down due to heat, and on the other hand, continuously keeping heat speed operation would consume a large amount of electrical power and may burden the power supply device. Considering policies of energy saving and carbon reduction, the manufacturers have proposed a fan speed control system that detects the temperature of a heat source and synchronously adjusts the rotational speeds of all fans. For example, when the heat source is at a lower temperature, all the fans are set to operate at lower speeds; and when the heat source is at a higher temperature, all the fans are put in high-speed operations.

However, such a known fan speed control system, when put into use, suffers certain problems that may need further improvements:

(1) There may be differences of temperature among all the heat sources and control of adjusting rotational speeds in a synchronous manner may suffer difficulty for decision making. If a low-temperature heat source is taken as a reference for adjustment, then the heat generated by a high-temperature heat source may not be effectively removed. On the other hand, if the high-temperature heat source is taken as a reference, then extra electrical power may get wasted at the low-temperature heat source.

(2) The rotational speeds of the fans are adjusted in a passive manner according to the measurements of temperatures. Thus, when a heat source is put into high power operation and thus generates a huge amount of heat, adjusting the rotational speeds in such a way may not be timely responsive and the heat source may reach a temperature beyond a tolerable upper temperature limit.

### SUMMARY OF THE INVENTION

In view of the above problems and drawbacks, the present invention aims to provide an asynchronous temperature control integrated device that conducts an instantaneous and effective driving operation, in a manner of being free of extra power consumption, on individual heat sources of a graphics card to individually control heat dissipation devices associated with the heat sources.

The primary objective of the present invention is that temperatures of heat sources at different sites on a graphics card are monitored and heat dissipation devices that respectively correspond to the heat sources are controlled individually such that output powers of the heat dissipation devise are generally proportional to the temperatures of the heat sources.

To achieve the above objective, the present invention provides a structure that comprises: graphics card body, which comprises a graphics processor and a power supply circuit arranged at one side of the graphics processor. A first heat dissipation device is arranged on the graphics processor and at least one first temperature sensor is arranged at one side of the first heat dissipation device. At least one second heat dissipation device is arranged on the power supply circuit and at least one second temperature sensor is arranged at one side of the second heat dissipation device. A control device is arranged on the graphics card body and is electrically connected to the first temperature sensor and the second temperature sensor the control device to individually control heat dissipation performances of the first heat dissipation device and the second heat dissipation device. A user, when operating the present invention, may find that two major heat sources of the graphics card body (which are respectively the graphics processor and the power supply circuit) are each provided with a heat dissipation device and the temperatures of the two heat sources are respectively detected by the first temperature sensor and the second temperature sensor so that the control device may regulate the output power of the first heat dissipation device or the second heat dissipation device individually, based on the results of detection to correspondingly handle different levels of heat generation. As such, excessive consumption of electrical power can be prevented and the output powers of the heat dissipation devices can be adjusted in a timely and individual manner.

Thus, the present invention may overcome the drawbacks of the known fan speed control systems that suffer shortcoming by synchronously adjusting the rotational speeds of the fans that may not timely responsive to desired heat dissipation performance and may consume extra electrical power.

The foregoing objectives and summary provide only a brief introduction to the present invention. To fully appreciate these and other objects of the present invention as well as the invention itself, all of which will become apparent to those skilled in the art, the following detailed description of the invention and the claims should be read in conjunction with the accompanying drawings. Throughout the specification and drawings identical reference numerals refer to identical or similar parts.

Many other advantages and features of the present invention will become manifest to those versed in the art upon making reference to the detailed description and the accompanying sheets of drawings in which a preferred structural embodiment incorporating the principles of the present invention is shown by way of illustrative example.

### BRIEF DESCRIPTION OF THE DRAWINGS

FIG. 1 is a perspective view showing a preferred embodiment of the present invention.

FIG. 2 is an exploded view of the preferred embodiment of the present invention.

FIG. 3 is a schematic view showing an application of the preferred embodiment of the present invention.

FIG. 4 is a plot demonstrating a temperature-rotational speed relationship provided by the preferred embodiment of the present invention.

FIG. 5 is an exploded view showing another preferred embodiment of the present invention.

FIG. 6 is a schematic view showing an application of said another preferred embodiment of the present invention.

FIG. 7 is another schematic view showing an application of said another preferred embodiment of the present invention.

FIG. 8 is a plot demonstrating a temperature-rotational speed relationship provided by said another preferred embodiment of the present invention.

FIG. 9 is an exploded view showing a further embodiment of the present invention.

FIG. 10 is a plot demonstrating a three-dimensional rotational speed relationship provided by said further embodiment of the present invention.

### DETAILED DESCRIPTION OF THE PREFERRED EMBODIMENTS

The following descriptions are exemplary embodiments only, and are not intended to limit the scope, applicability or configuration of the invention in any way. Rather, the following description provides a convenient illustration for implementing exemplary embodiments of the invention. Various changes to the described embodiments may be made in the function and arrangement of the elements described without departing from the scope of the invention as set forth in the appended claims.

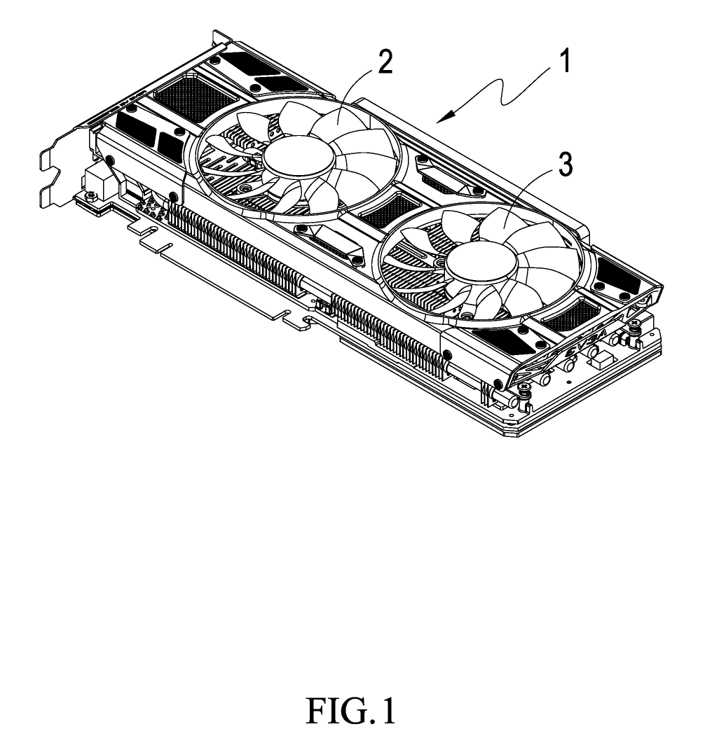

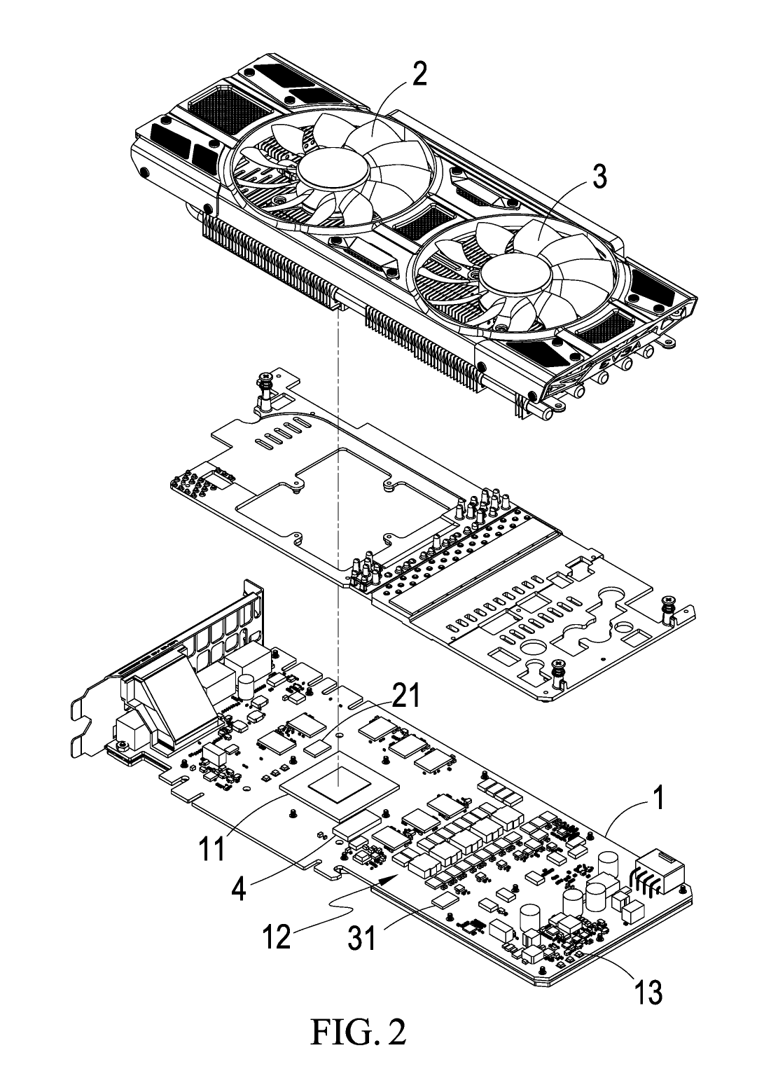

As shown in FIGS. 1 and 2, the present invention comprises the following components:

a graphics card body 1, which comprises a graphics processor 11 and a power supply circuit 12 arranged at one side of the graphics processor 11;

a first heat dissipation device 2, which is arranged on the graphics processor 11, wherein a heat dissipation fan is taken as an example in the present invention;

at least one first temperature sensor 21, which is arranged at one side of the first heat dissipation device 2;

at least one second heat dissipation device 3, which is arranged on the power supply circuit 12, wherein a heat dissipation fan is taken as an example in this invention;

at least one second temperature sensor 31, which is arranged at one side of the second heat dissipation device 3;

at least one light emission element 13, which is arranged at one side of the first temperature sensor 21 and the second temperature sensor 31 to issue temperature alarms with different colors of light; and

a control device 4, which is arranged on the graphics card body 1 and is electrically connected to the first temperature sensor 21 and the second temperature sensor 31 to individually control heat dissipation performances of the first heat dissipation device 2 and the second heat dissipation device 3.

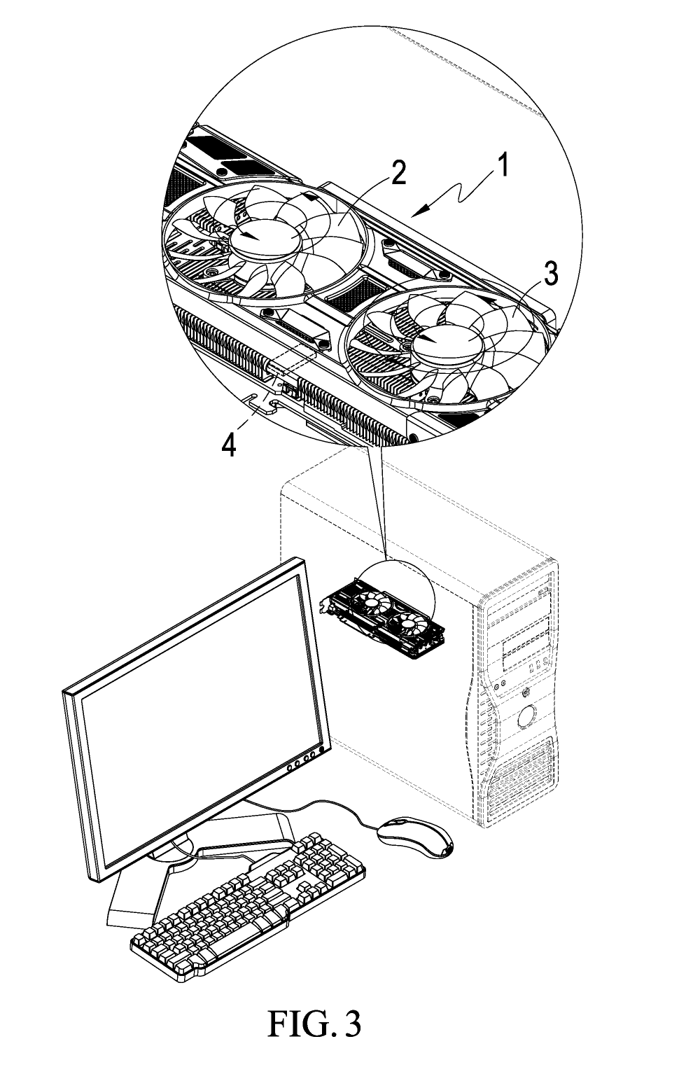

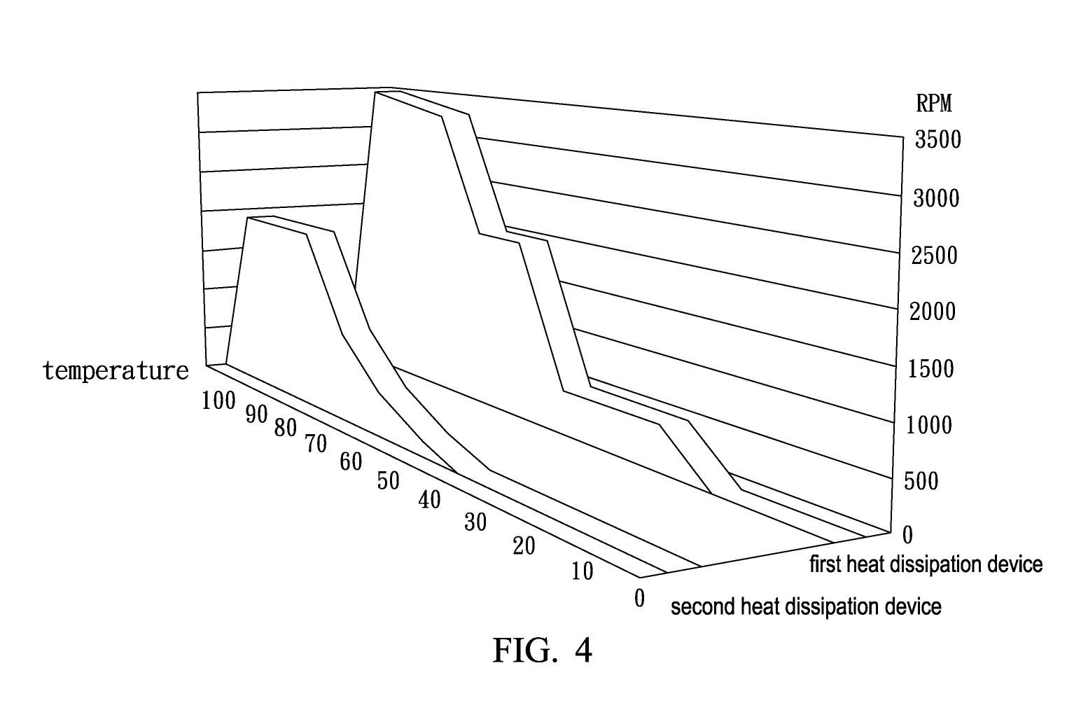

As shown in FIGS. 1-4, these drawings clearly show that the present invention is structured such that the first heat dissipation device 2 and the second heat dissipation device 3 are respectively set on two major heat sources, which are respectively the graphics processor 11 and the power supply circuit 12, of the graphics card body 1 and the first and second temperature sensors 21, 31 are arranged to detect the temperatures of the two heat sources and transmit temperature data measured thereby to the control device 4, such that the control device 4 is allowed to apply individual and different controls to heat dissipation performances (such as different rotational speeds of fans) associated therewith different ones of the heat sources according to the temperature data thereof. For example, when temperature data of the first temperature sensor 21 is 70° C. and the temperature data of the second temperature sensor 31 is 50° C., the control device 4 sets the rotational speed of the first heat dissipation device 2 to 2000 rpm and sets the rotational speed of the second heat dissipation device 3 to 500 rpm, and uses a single color, or multiple colors, or a mixture of colors of the light emitting from the light emission element 13 to reflect the status of temperature conditions. As such, different performances or operations of heat dissipation are applied respectively to different levels of heat generated to allow the heat dissipation devices respectively associated with various heat sources on the graphics card body 1 to be operated in an asynchronous manner to distribute, in a more efficient way, electrical power to fans that are set at relatively high rotational speeds.

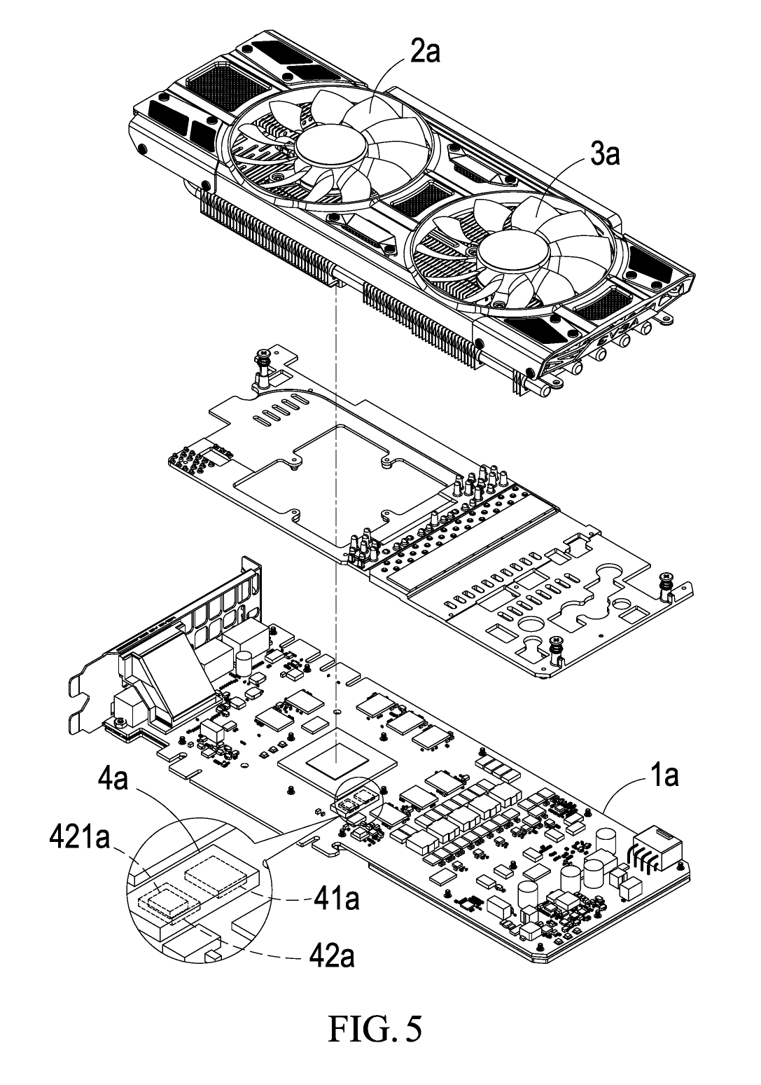

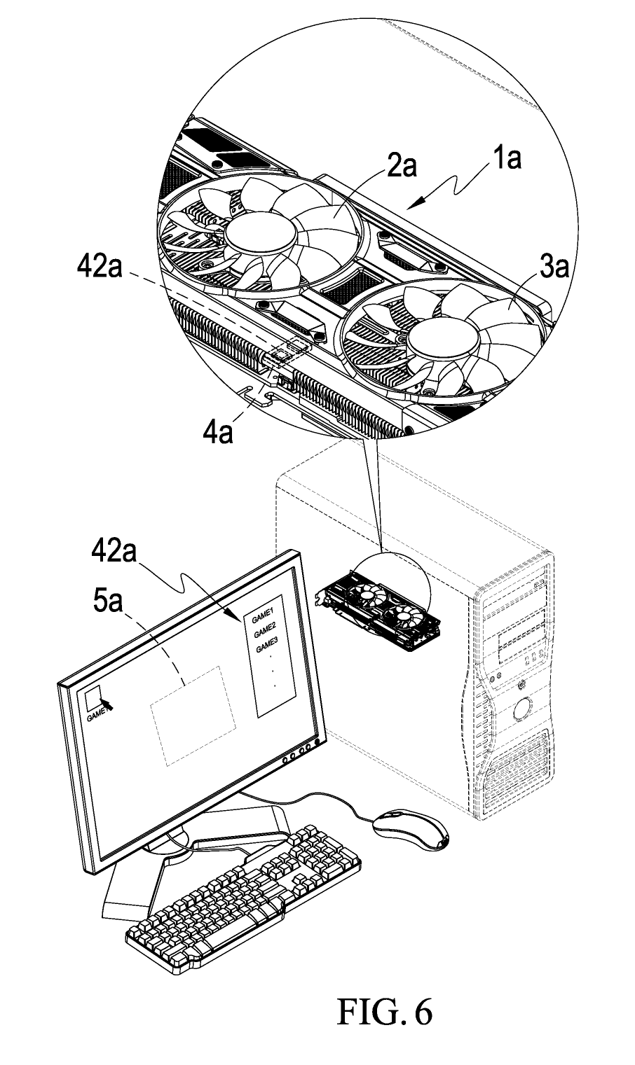

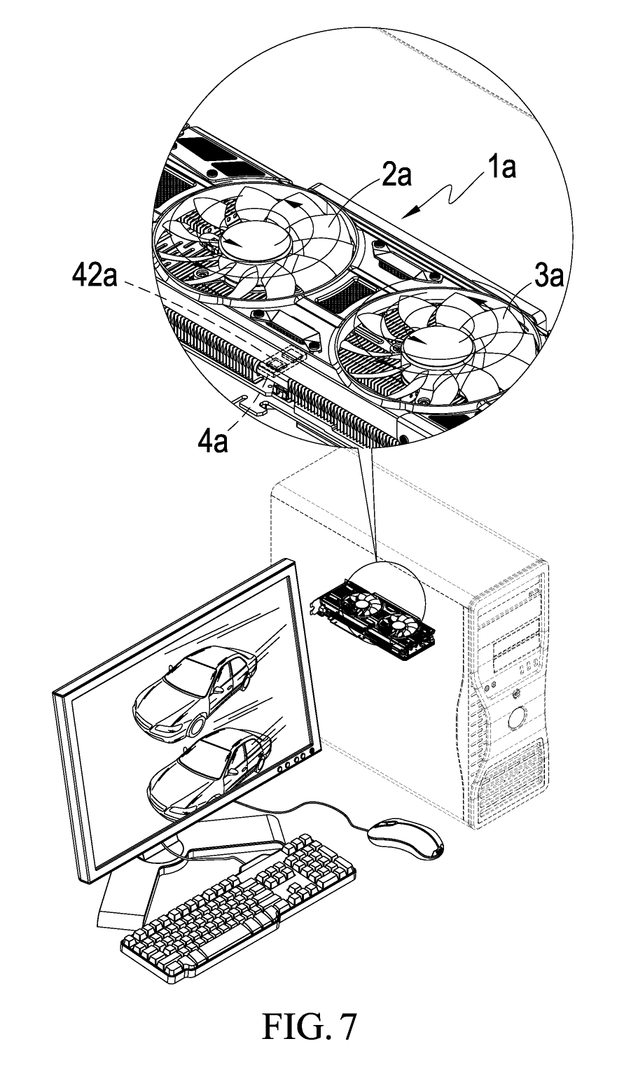

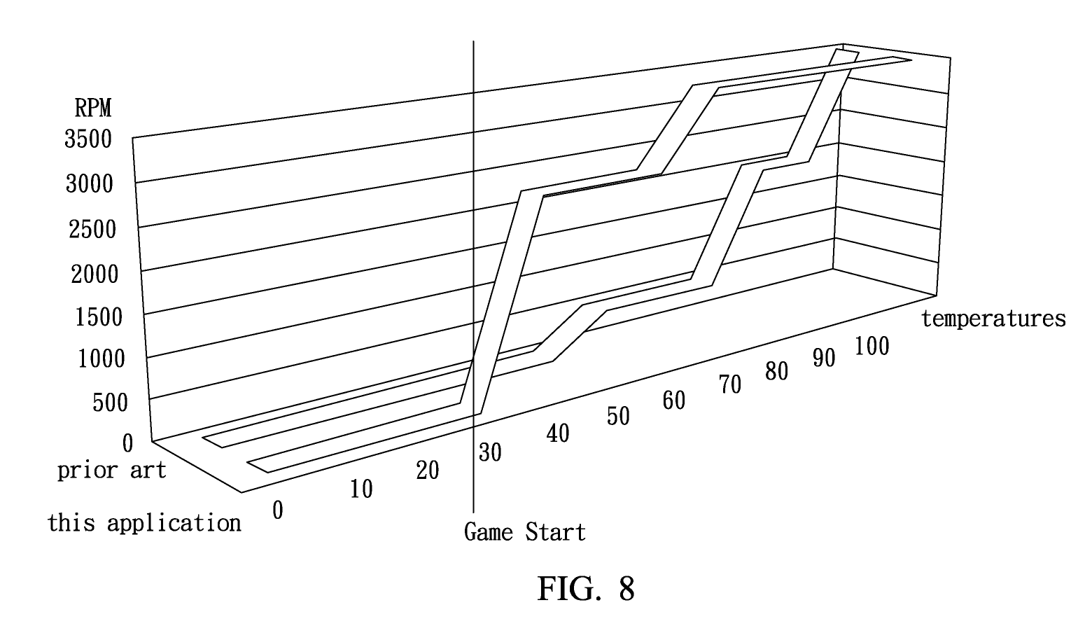

As shown in FIGS. 5-8, another embodiment is illustrated and the instant embodiment is generally similar to the previous embodiment with a difference that the control device 4a is additionally provided with a high power drive module 41a for driving, in a forced manner, the first heat dissipation device 2a and the second heat dissipation device 3a to generate maximum available output power. The control device 4a comprises a scenario database 42a that is electrically connected to the high power drive module 41a to store therein a list of at least one high power program. The scenario database 42a comprises a detection unit 421a, which detects an operation of activation/deactivation of the high power program. As such, a user may operates a control module 5a to build up a list of high power programs (such as full 3D game programs) in the scenario database 42a, so that when such programs are activated, the detection unit 421a may detect such activation operations to transmit a signal notifying the high power drive module 41a to issue a drive command that drives and forces the first heat dissipation device 2a and the second heat dissipation device 3a to generate the maximum output power, thereby providing an environment of high power dissipation performance before temperature rises start on the graphics card body 1a so as to help prevent, in advance, generation of a high temperature situation.

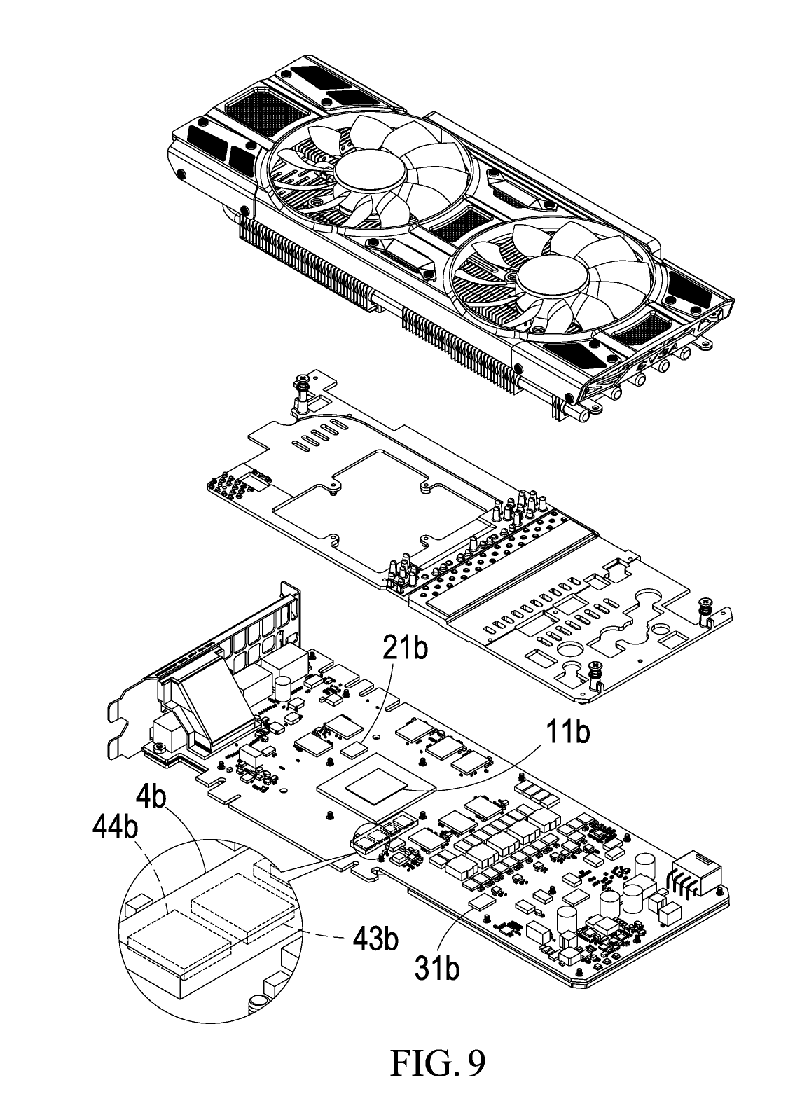

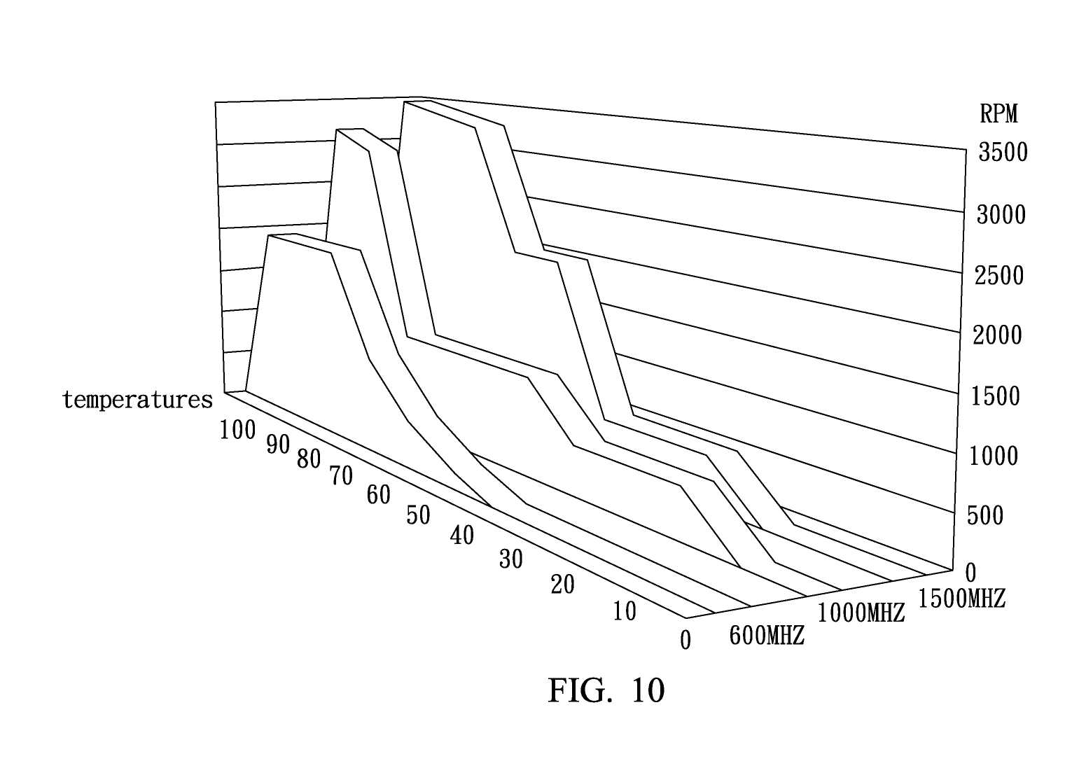

As shown in FIGS. 9-10, a further embodiment is shown and the instant embodiment comprises a control device 4b that comprises a frequency feed-back module 43b that reads and accesses working frequency data of the graphics processor 11b and an integration unit 44b that combines and integrates the temperature data provided by the first temperature sensor 21b and the second temperature sensor 31b and the working frequency data of the graphics processor 11b to generate control information. As such, conditions or factors that the control device 4b can take into consideration include both temperature and frequency so that the control information so generated can be used to more precisely set up desired heat dissipation performances (which can be for example fan rotational speeds) of the heat dissipation devices. FIG. 10 provides a plot demonstrating a three-dimensional relationship among the temperatures, the working frequency of the graphics processor 11b, and the fan rotational speeds.

It will be understood that each of the elements described above, or two or more together may also find a useful application in other types of methods differing from the type described above.

While certain novel features of this invention have been shown and described and are pointed out in the annexed claim, it is not intended to be limited to the details above, since it will be understood that various omissions, modifications, substitutions and changes in the forms and details of the device illustrated and in its operation can be made by those skilled in the art without departing in any way from the claims of the present invention.

I claim:

1. An asynchronous temperature control integrated device, comprising:
a graphics card body, which comprises a graphics processor and a power supply circuit arranged at one side of the graphics processor;
a first heat dissipation device, which is arranged on the graphics processor;
at least one first temperature sensor, which is arranged at one side of the first heat dissipation device;
at least one second heat dissipation device, which is arranged on the power supply circuit;
at least one second temperature sensor, which is arranged at one side of the second heat dissipation device; and
a control device, which is arranged on the graphics card body and is electrically connected to the first temperature sensor and the second temperature sensor to individually control heat dissipation performances of the first heat dissipation device and the second heat dissipation device.

2. The asynchronous temperature control integrated device according to claim 1 further comprising a control module in information connection with the control device.

3. The asynchronous temperature control integrated device according to claim 1, wherein the first temperature sensor and the second temperature sensor are provided, at one side thereof, with at least one light emission element, which is operable to issue temperature alarms with different colors of light.

4. The asynchronous temperature control integrated device according to claim 1, wherein the control device comprises a high power drive module, which is operable to drive and force the first heat dissipation device and the second heat dissipation device to generate outputs of available maximum power.

5. The asynchronous temperature control integrated device according to claim 4, wherein the control device comprises a scenario database electrically connected to the high power drive module and loaded therein with a list of at least one high power program.

6. The asynchronous temperature control integrated device according to claim 5, wherein the scenario database comprises a detection unit, which is operable to detect activation and deactivation of the high power program.

7. The asynchronous temperature control integrated device according to claim 1, wherein the control device comprises a frequency feed-back module, which reads and accesses working frequency data of the graphics processor.

8. The asynchronous temperature control integrated device according to claim 7, wherein the control device comprises an integration unit, which combines and integrates temperature data of the first temperature sensor and the second temperature sensor and the working frequency data of the graphics processor to generate control information.
